(19) United States
(12) Patent Application Publication
(10) Pub. No.: US 2005/0139842 A1
(43) Pub. Date: Jun. 30, 2005

(54) Semiconductor light emitting element and fabrication method thereof

(75) Inventors: Hitoshi Murofushi, Saitama (JP); Shiro Takeda, Saitama (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sanken Electric Co., Ltd., Saitama (JP)

(21) Appl. No.: 11/023,947

(22) Filed: Dec. 27, 2004

(30) Foreign Application Priority Data
Dec. 25, 2003 (JP) 2003-429716

(51) Int. Cl. H01L 27/15

(52) U.S. Cl. 257/79

(57) ABSTRACT

Provided between a window layer and a protection layer is a light transmissive layer having a refraction index which is between the refraction indexes of the window layer and protection layer. The refraction index n₂ of the light transmissive layer is, for example, within ±20% of the geometric average of the refraction indexes of the window layer and protection layer. The thickness T of the light transmissive layer satisfies {(λ/4n₂)×(2m+1)−(λ/8n₂)≦T≦(λ/4n₂)×(2m+1)+(λ/8n₂)} where λ represents the wavelength of emitted light and m represents a positive integer not smaller than 0.

### CROSS-REFERENCES TO RELATED APPLICATIONS

This application is based on Japanese Patent Application No. 2003-429716 filed on Dec. 25, 2003, the disclosure of which is incorporated herein by reference in its entirety.

### BACKGROUND OF THE INVENTION

1. Field of the Invention

The present invention relates to a semiconductor light emitting element such as a light emitting diode, a semiconductor laser, etc. and a fabrication method thereof.

2. Description of the Related Art

To improve the luminance of a semiconductor light emitting element such as a light emitting diode, a semiconductor laser, etc., it is extremely important to efficiently extract the light emitted in the active layer of the light emitting element to the outside of the element. That is, it is necessary to restrict light reflection on the surface of the light emitting element as much as possible to let out the emitted light to the outside of the element and increase the so-called light extraction efficiency.

As a means for restricting light reflection on the surface of the light emitting element and increasing the light extraction efficiency, there is a method for restricting total reflection on the surface of the light emitting element. To be more specific, the ratio of the light emitted through the element surface or the light total-reflected on the element surface is determined by the refraction index of the surface layer of the element and that of the outside world (including a transparent protection layer or the like). As the difference in the refraction index between the surface layer and the outside world is smaller, the critical angle is larger. The critical angle is an angle of light incidence to the interface between the surface layer and the outside world. Assume that the refraction index of the surface layer is n₁₁ and the refraction index of the outside world is n₁₂. In this case, the critical angle θ is expressed by the following mathematical expression 1.
θ=sin⁻¹(n₁₁/n₁₂) (Mathematical expression 1)

As obvious from the mathematical expression 1, as the difference between the refraction index n₁₁ of the surface layer and the refraction index n₁₂ of the outside world is smaller, that is, as the ratio n₁₁/n₁₂ is closer to 1, the critical angle θ takes a larger value (a value closer to 90°). Light having a larger angle of incidence than the critical angle θ is total-reflected on the interface and thus is not let out to the outside. Accordingly, as the difference between the refraction indexes is smaller, the ratio of the light to be total-reflected is smaller, so that more light is emitted to the outside world resulting in achieving a higher light extraction efficiency.

However, a general light emitting element is formed of a surface layer made of gallium arsenide or the like having a refraction index of 2 to 4, which is molded with resin having a refraction index of about 1.5. Since the difference in the refraction index between the surface layer and the outside world is relatively large, the light extraction efficiency is relatively low. Therefore, various methods for improving the light extraction efficiency have been developed.

As one of such methods, there is a technique for forming a light scattering layer having recesses and bosses on its surface, on the optical window from which light is extracted, as disclosed in Unexamined Japanese Patent Application KOKAI Publication No. H10-163525 (Patent Document 1) and Unexamined Japanese Patent Application KOKAI Publication No. H11-46005 (Patent Document 2). By forming the light scattering layer having recesses and bosses on its surface, it is expected that total-reflection of the light on the surface of the light scattering layer be restricted and the light be efficiently emitted to the outside of the element.

However, the formation of such a scattering layer has problems in the viewpoints of workability and repeatability. For example, according to the light scattering layer forming method disclosed in the Patent Document 1, scattering particles need to be uniformly dispersed. According to the light scattering layer forming method disclosed in the Patent Document 2, air bubbles need to be uniformly dispersed in a liquid-like film. However, it is extremely difficult to carry out the dispersion with a good repeatability and fabricate light emitting elements having a high uniformity and a desired luminance at a high yield.

There may be considered a method for forming recesses and bosses directly on the optical window. However, this method also has the workability problem, and formation of recesses and bosses might give an adverse influence on the electric property of the light emitting element.

As such, there have conventionally been demanded a semiconductor light emitting element which has a high efficiency of light extraction from the element surface achieved by suitably restricted light reflection on the element surface, and can be fabricated with a good workability and repeatability, and a fabrication method thereof.

### BRIEF SUMMARY OF THE INVENTION

In view of the above-described circumstance, it is an object of the present invention to provide a semiconductor light emitting element which has a high light extraction efficiency and can be fabricated with a good workability and repeatability, and a fabrication method thereof.

Another object of the present invention is to provide a semiconductor light emitting element with suitably restricted reflection of emitted light on the element surface, and a fabrication method thereof.

To achieve the above objects, a semiconductor light emitting element according to a first aspect of the present invention comprises:
a semiconductor layer which forms an optical window;
a first light transmissive layer which is formed on the semiconductor layer; and
a second light transmissive layer which is formed on the first light transmissive layer.

A refraction index n₂ of the first light transmissive layer is within a range of not smaller than {(n₁×n₃)^{1/2}×0.8} and not larger than {(n₁×n₃)^{1/2}×1.2} where n₁ represents a refraction index of the semiconductor layer and n₃ represents a refraction index of the second light transmissive layer.

A thickness of the first light transmissive layer is within a range of not smaller than {(λ/4n₂)×(2m+1)−(λ/8n₂)} and not larger than {(λ/4n₂)×(2m+1)+(λ/8n₂)} where λ represents a wavelength of emitted light and m represents a positive integer not smaller than 0.

In the semiconductor light emitting element having the above-described configuration, the first light transmissive layer may be formed by stacking a plurality of layers having different refraction indexes.

A refraction index n₂ⱼ of each of the layers of the first light transmissive layer is within a range defined between a refraction index n₂ᵢ of a layer adjoining the each layer at a side of the semiconductor layer and a refraction index n₂ₖ of a layer adjoining the each layer at a side of the second light transmissive layer.

In this case, the refraction index n₂ⱼ of each layer of the first light transmissive layer (19) is within a range of not smaller than {(n₂ᵢ×n₂ₖ)^{1/2}×0.8} and not larger than {(n₂ᵢ'n₂ₖ)^{1/2}×1.2}.

It is preferred that a thickness of each layer of the first light transmissive layer be within a range of not smaller than {(λ/4n₂ⱼ)×(2l+1)−(λ/8n₂ⱼ)} and not larger than {(λ/4n₂ⱼ)×(2l+1)+(λ/8n₂ⱼ)} where λ represents a wavelength of emitted light and 1 represents a positive integer not smaller than 0.

In the semiconductor light emitting element having the above-described configuration, the second light transmissive layer may be formed of a protection film.

In the semiconductor light emitting element having the above-described configuration, the first light transmissive layer is made of, for example, an inorganic dielectric material. In this case, separation of the first light transmissive layer and the semiconductor layer is prevented and a high reliability can be obtained for a long time.

To achieve the above objects, a semiconductor light emitting element according to a second aspect of the present invention comprises:
a semiconductor layer which forms an optical window; and
a first light transmissive layer which is formed on the semiconductor layer.

The semiconductor light emitting element is structured such that light emitted from the semiconductor layer is emitted to external atmosphere by passing through the first light transmissive layer.

A refraction index n₂ of the first light transmissive layer is within a range of not smaller than {(n₁×n₃)^{1/2}×0.8} and not larger than {(n₁×n₃)^{1/2}×1.2} where n₁ represents a refraction index of the semiconductor layer and n₃ represents a refraction index of atmosphere.

A thickness of the first light transmissive layer is within a range of not smaller than {(λ/4n₂)×(2m+1)−(λ/8n₂)} and not larger than {(λ/4n₂)×(2m+1)+(λ/8n₂)} where λ represents a wavelength of emitted light and m represents a positive integer not smaller than 0.

According to the semiconductor light emitting element of the present invention, light emitted from the semiconductor layer is emitted to the atmosphere by passing through the first light transmissive layer. The light extraction efficiency showing the degree of light emission to the atmosphere can be improved based on the relationship among the refraction index n₂ of the semiconductor layer, the refraction index n₂ of the first light transmissive layer, and the refraction index n₃ of the second light transmissive layer.

To achieve the above objects, a semiconductor light emitting element according to a third aspect of the present invention comprises:
a semiconductor layer which emits light having a wavelength λ caused by recombination of holes and electrons; and
a first light transmissive layer which is stacked on the semiconductor layer.

A second light transmissive layer is stacked on the first light transmissive layer at the side opposite to the side the semiconductor layer is disposed.

The light emitting element is structured such that light emitted from the semiconductor layer is guided to the second light transmissive layer via the first light transmissive layer and thus guided to outside.

At least a part of the semiconductor layer from which part light is emitted to the first light transmissive layer has a refraction index n₁, the first light transmissive layer has a refraction index n₂, and the second light transmissive layer has a refraction index n₃.

A refraction index n₂ of the first light transmissive layer is within a range of not smaller than {(n₁×n₃)^{1/2}×0.8} and not larger than {(n₁×n₃)^{1/2}×1.2}.

A thickness of the first light transmissive layer is within a range of not smaller than {(λ/4n₂)×(2m+1)−(λ/8n₂)} and not larger than {(λ/4n₂)×(2m+1)+(λ/8n₂)} where m represents a positive integer not smaller than 0.

According to the present invention, the light extraction efficiency showing the degree of light emission from the semiconductor light emitting element to the outside can be improved based on the relationship among the refraction index n₁ of the semiconductor layer, the refraction index n₂ of the first light transmissive layer, and the refraction index n₃ of the second light transmissive layer.

Further, according to the semiconductor light emitting element of the present invention, there is no need of applying any special process for improving the light extraction efficiency, making it possible to improve workability and repeatability during fabrication of the element.

In the semiconductor light emitting element, the semiconductor layer includes an N-type carrier injection layer for generating electrons, a P-type carrier injection layer for generating holes, and an active layer for generating light by recombination of electrons injected from the N-type carrier injection layer and holes injected from the P-type carrier injection layer.

The N-type carrier injection layer, the active layer, the P-type carrier injection layer, and the first light transmissive layer are stacked in this order.

A reflection film may be formed on any part that is included in a region starting from the active layer toward the N-type carrier injection layer, so that light emitted from the active layer toward the N-type carrier injection layer is reflected on the reflection film and thus guided toward the first light transmissive layer.

According to the semiconductor light emitting element of the present invention, light emitted from the active layer toward the N-type carrier injection layer is reflected on the reflection film toward the first light transmissive layer. Because of this, the amount of light to be guided toward the first light transmissive layer can be increased. This leads to improvement in the light extraction efficiency of the semiconductor light emitting element.

In the semiconductor light emitting element, a protection film having the refraction index n₃ may be formed as the second light transmissive layer. Or, in the semiconductor light emitting element, the second light transmissive layer may be external atmosphere, and light emitted from the semiconductor layer may be emitted to the external atmosphere by passing through the first light transmissive layer.

To achieve the above objects, a fabrication method of a semiconductor light emitting element according to a fourth aspect of the present invention is for fabricating a semiconductor light emitting element including a semiconductor layer forming an optical window, a first light transmissive layer formed on the semiconductor layer, and a second light transmissive layer formed on the first light transmissive layer, and comprises the step of forming the first light transmissive layer by using a material having a refraction index n₂ which is within a range of not smaller than {(n₁×n₃)^{1/2}×0.8} and not larger than {(n₁×n₃)^{1/2}×1.2} (where n₁ represents a refraction index of the semiconductor layer and n₃ represents a refraction index of the second light transmissive layer), and by giving a thickness which is within a range of not smaller than {(λ/4n₂)×(2m+1)−(λ/8n₂)} and not larger than {(λ/4n₂)×(2m+1)+(λ/8n₂)} (where λ represents a wavelength of emitted light and m represents a positive integer not smaller than 0).

According to the above-described fabrication method, the first light transmissive layer may be formed by stacking a plurality of layers having different refraction indexes.

Each of the layers of the first light transmissive layer may be formed by using a material having a refraction index n₂ⱼ which is within a range of not smaller than {(n₂ᵢ×n₂ₖ)^{1/2}×0.8} and not larger than {(n₂ᵢ×n₂ₖ)^{1/2}×0.2} (where n₂ᵢ represents a refraction index of a layer adjoining the each layer at a side of the semiconductor layer and n₂ₖ represents a refraction index of a layer adjoining the each layer at a side of the second light transmissive layer), by giving a thickness which is within a range of not smaller than {(λ/4n₂ⱼ)×(2l+1)−(λ/8n₂ⱼ)} and not larger than {(λ/4n₂ⱼ)×(2l+1)+(λ/8n₂ⱼ)} (where λ represents a wavelength of emitted light and 1 represents a positive integer not smaller than 0).

According to the present invention, there are provided a semiconductor light emitting element which has a high light extraction efficiency and can be fabricated with a good workability and repeatability, and a fabrication method thereof.

Further, according to the present invention, there are provided a semiconductor light emitting element with suitably restricted reflection of emitted light on the element surface, and a fabrication method thereof.

### BRIEF DESCRIPTION OF THE DRAWINGS

These objects and other objects and advantages of the present invention will become more apparent upon reading of the following detailed description and the accompanying drawings in which:

FIG. 1 is a diagram showing the structure of a semiconductor light emitting element according to the embodiment of the present invention.

FIG. 2A is a diagram showing a fabrication process of a semiconductor base.

FIG. 2B is a diagram showing a fabrication process of a light transmissive layer.

FIG. 2C is a diagram showing a fabrication process of an anode electrode.

FIG. 3 is a diagram showing a modified example of the semiconductor light emitting element according to the embodiment of the present invention.

FIG. 4 is a diagram showing the results of measuring light output of the semiconductor light emitting element according to the embodiment of the present invention.

FIG. 5 is a diagram showing the results of measuring light output of a lamp utilizing the semiconductor light emitting element according to the embodiment of the present invention.

### DETAILED DESCRIPTION OF THE INVENTION

A semiconductor light emitting element according to the embodiment of the present invention will now be specifically explained with reference to the drawings. The following will explain, as an example, a case where a semiconductor light emitting element forms a light emitting diode.

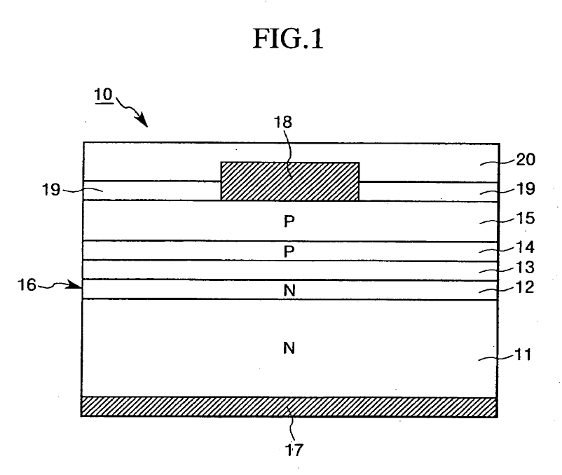

FIG. 1 shows a cross-sectional view of a semiconductor light emitting element 10 according to the embodiment of the present invention. As shown in FIG. 1, the semiconductor light emitting element 10 according to the present embodiment comprises a semiconductor base 16 including an N-type substrate 11, an N-type auxiliary layer 12, an active layer 13, a P-type auxiliary layer 14, and a window layer 15. The semiconductor light emitting element 10 is formed of a cathode electrode 17 which is formed on one surface of the semiconductor base 16, and of an anode electrode 18, a light transmissive layer 19, and a protection layer 20 which are formed on the other surface thereof.

As shown in FIG. 1, the semiconductor light emitting element 10 has a structure in which the anode electrode 18, the light transmissive layer 19, and the protection layer 20 are stacked on one side of the semiconductor base 16. The protection layer 20 is stacked on one side of the light transmissive layer 19. The anode electrode 18 is formed so as to penetrate the central portion of the light transmissive layer 19, with its one end surface residing in the protection layer 20 and its other end surface contacting one end surface of the semiconductor base 16 on one side (i.e., contacting the end surface of the window layer 15).

The cathode electrode 17 is stacked on the other side of the semiconductor base 16, which opposes to the one side. The anode electrode 18 and the cathode electrode 17 are provided so as to face each other via the semiconductor base 16.

As shown in FIG. 1, the semiconductor base 16 has a structure in which the N-type auxiliary layer 12 is stacked on one side of the N-type substrate 11, the active layer 13 is stacked on one side of the N-type auxiliary layer 12, the P-type auxiliary layer is stacked on one side of the active layer 13, and the window layer 15 is stacked on one side of the P-type auxiliary layer 14.

In the semiconductor base 16, the N-type substrate 11 and the N-type auxiliary layer 12 are semiconductor layers for generating N-type carriers (electrons) and serve as N-type carrier injection layers for injecting N-type carriers into the active layer 13. Further, in the semiconductor base 16, the P-type auxiliary layer 14 and the window layer 15 are semiconductor layers for generating P-type carriers (holes) and serve as P-type carrier injection layers for injecting P-type carriers into the active layer 13.

The N-type substrate 11 is formed of an N-type semiconductor substrate made of gallium arsenide (GaAs) or the like. The N-type substrate 11 has, for example, an impurity concentration of about 1×10¹⁸ cm⁻³, and a thickness of about 250 μm.

The N-type auxiliary layer 12 is formed on one surface of the N-type substrate 11, and is formed of a semiconductor layer made of aluminum-gallium-indium-phosphorus (AlGaInP) or the like. The N-type auxiliary layer 12 is formed by, for example, epitaxial growth method. The N-type auxiliary layer 12 has, for example, an impurity concentration of about 5×10¹⁷ cm⁻³, and a thickness of about 2 μm.

The active layer 13 is formed on the N-type auxiliary layer 12, and is formed of a semiconductor layer made of AlGaInP or the like. The active layer 13 is formed by, for example, epitaxial growth method. The active layer 13 is formed with a thickness of about 0.5 μm. The active layer 13 is a light emitting layer which emits light by electroluminescence. The active layer 13 causes light emission when carriers (holes and electrons) injected thereinto from both surfaces thereof are recombined. When the semiconductor light emitting element 10 is supplied with power from an external power source through the anode electrode 18 and the cathode electrode 17 so that a current flows between the anode electrode 18 and the cathode electrode 17, carriers are injected into the active layer 13.

The P-type auxiliary layer 14 is formed on the active layer 13, and is formed of a semiconductor layer made of AlGaInP or the like. The P-type auxiliary layer 14 is formed by, for example epitaxial growth method, and formed with, for example, an impurity concentration of about 5×10¹⁷ cm⁻³, and a thickness of about 2 μm.

The relative proportion of Al in AlGaInP that makes up the N-type auxiliary layer 12 or the P-type auxiliary layer 14 is set higher than the relative proportion of Al in AlGaInP that makes up the active layer 13. By this setting, it is possible to efficiently emit light generated by carrier recombination that takes place in the active layer 13 to the outside of the active layer 13.

The N-type auxiliary layer 12 and the P-type auxiliary layer 14 may be called N-type cladding layer and P-type cladding layer respectively.

The window layer 15 is formed on the P-type auxiliary layer 14, and is formed of a semiconductor layer made of gallium-phosphorus (GaP) doped with a P-type impurity or the like. The window layer 15 is also called current diffusion layer. The window layer 15 is formed by, for example, epitaxial growth method, and is formed with an impurity concentration of about 5×10¹⁷ cm⁻³ and a thickness of about 2 μm. The window layer 15 forms one surface of the semiconductor base 16, and as will be specifically explained later, forms an optical window from which light emitted from the active layer 13 is extracted to the outside.

A current block layer made of N-type AlGaInP or the like may be provided between the P-type auxiliary layer 14 and the window layer 15.

The cathode electrode 17 formed of a gold-germanium alloy (Au—Ge) film, a metal multilayer film made of Au—Ge, nickel (Ni), and gold (Au), or the like is formed on the N-type substrate 11 which forms one surface of the semiconductor base 16 having the above-described configuration.

The anode electrode 18 formed of a metal multilayer film made of gold-zinc alloy (Au—Zn), gold-beryllium-chromium alloy (Au—Be—Cr), gold (Au), and the like is formed on generally the center portion of the window layer 15 which forms the other surface of the semiconductor base 16. The anode electrode 18 is provided in generally a circular shape on the window layer 15, and the regions of the window layer 15 that are not covered with the anode electrode 18 form the window regions for the emitted light.

The light transmissive layer 19 is provided on the regions of the window layer 15 that are not covered with the anode electrode 18. The light transmissive layer 19 is made of an inorganic dielectric material such as titanium oxide (TiOₓ), zinc oxide (ZnO), silicon nitride (SiN), zirconium oxide (ZrO), zinc sulfide (ZnS), or the like which is transmissive of light emitted from the active layer 13, and as will be described later, has a predetermined refraction index and thickness.

The protection layer 20 is formed on the light transmissive layer 19. The protection layer 20 is made of a highly transmissive material such as epoxy resin or the like, and has a function for protecting the semiconductor base 16 from moisture or the like.

In the semiconductor light emitting element 10 having the above-described configuration, the light transmissive layer 19 has a function for suitably restricting light reflection between the window layer 15 and the protection layer 20. With this function of the light transmissive layer 19, emitted light that is introduced from the active layer 13 into the window layer 15 is efficiently let out to the outside of the element, realizing a high light extraction efficiency. The light transmissive layer 19 will now be specifically explained below.

The light transmissive layer 19 intervening between the window layer 15 and the protection layer 20 is made of a material having a refraction index n₂ which is between the refraction index n₁ of the window layer 15 and the refraction index n₃ of the protection layer 20. In the present example, the refraction index n₂ of the light transmissive layer 19 is set within a range of ±20% of the geometric average of the refraction index n₁ of the window layer 15 and the refraction index n₃ of the protection layer 20, i.e., within the range expressed by the following mathematical expression 2.
(n₁×n₃)^{1/2}×0.8≦n₂≦(n₁×n₃)^{1/2}×1.2 (Mathematical expression 2)

For example, in a case where the window layer 15 is formed using Gap (refraction index n₁=3.4) and the protection layer 20 is formed using epoxy resin (refraction index n₃=1.5), a material having a refraction index of not smaller than 1.81 (=(n₁×n₃)^{1/2}×0.8) and not larger than 2.71 (=(n₁×n₃)^{1/2}×1.2), for example, titanium oxide (refraction index 2.26) can be selected.

The thickness T of the light transmissive layer 19 is set so as to satisfy the following mathematical expression 3 using the refraction index n₂ of the light transmissive layer 19 and the wavelength λ of light emitted from the active layer 13.
(λ/4n₂)×(2m+1)−(λ/8n₂)≦T≦(λ/4n₂)×(2m+1)+(λ/8n₂) (Mathematical expression 3)
(where m represents a positive integer not smaller than 0)

By forming the light transmissive layer 19 with the refraction index n₂ satisfying the above mathematical expression 2 and the thickness T satisfying the above mathematical expression 3, lights reflected on the interface weaken each other or cancel each other by interference, restricting reflection on the interface.

It is preferred that m=0, 1, or 2 in the above mathematical expression 3. This is because if m is not smaller than 3, the thickness T becomes large, leading to a remarkable attenuation of light through the light transmissive layer 19.

Specifically, the thickness T of the light transmnissive layer 19 made of titanium oxide is, for example, 70.5 nm (705 Å). The wavelength λ of the light emitted from the active layer 13 made of AlGaInP is 560 to 650 nm. In a case where λ=620 nm, with the refraction index of titanium oxide (refraction index n₂ of the light transmissive layer 19) being about 2.2, the thickness T (70 nm) of the light transmissive layer 19 is a value between 105.67 nm (=(λ/4n₂)×(2m+1)+(λ/8n₂), m=0) and 35.23 nm (=(λ/4n₂)×(2m+1)−(λ/8n₂), m=0).

As explained above, by forming the light transmissive layer 19 made of a material having the predetermined refraction index n₂ to have the predetermined thickness T, it is possible to suitably restrict reflection on an interface encountered by the light before the light is emitted from the protection layer 20. As a result, it is possible to efficiently extract light which is emitted from the active layer 13 toward the window layer 15, to the outside via the light transmissive layer 19 and to increase the so-called light extraction efficiency.

The refraction index n₂ of the light transmissive layer 19 is set to a value between the refraction indexes n₁ and n₃ of the window layer 15 and protection layer 20 sandwiching the light transmissive layer 19, for example, to a value within a range of ±20% of the geometric average of the refraction indexes n₁ and n₃. By forming the light transmissive layer 19 to have a thickness enough to perform a desired interference effect by using a material having the refraction index n₂ within such a range, it is possible to suitably restrict reflection on the interface between layers.

According to the configuration in which the light transmissive layer 19 having these characteristics is provided, it is not required to form a recessed and bossed surface having workability, repeatability, and uniformity problems on the surface of the light transmissive layer 19, in order to achieve improvement in the brightness obtained by diffused reflection effect of such a recessed and bossed surface. To the contrary, it is preferred that the surface of the light transmissive layer 19 be substantially a mirror finished surface, in order to control light interference with a high degree of precision. A preferred depth of recesses and bosses of the surface of the light transmissive layer 19 is not larger than 1/10 of the wavelength λ of the light emitted from the active layer 13 (not larger than λ/10).

A fabrication method of a display element according to the present embodiment will now be explained. The example to be described below is merely one example, and the fabrication method is not limited to this example if there is any other method available that can obtain the same result.

First, by epitaxial growth method, the N-type auxiliary layer 12, the active layer 13, the P-type auxiliary layer 14, and the window layer 15 are stacked in this order on the N-type substrate 11 made of GaAs doped with an N-type impurity. As the epitaxial growth method, metalorganic chemical vapor deposition (MOCVD), molecular beam epitaxy (MBE), chemical beam epitaxy (CBE), molecular layer epitaxy (MLE), etc. may be employed.

In a case where depressurized MOCVD is employed, the layers can be formed in the manner described below. The N-type substrate 11 formed by doping an N-type impurity into GaAs is prepared. By employing MOCVD, the N-type auxiliary layer 12, the active layer 13, the P-type auxiliary layer 14, and the window layer 15 are sequentially formed on the N-type substrate 11 by vapor epitaxial growth.

Specifically, first, by using as material gases, TMA (trimethylaluminum), TEG (triethylgallium), TMIn (trimethylindium), and PH₃ (phosphin), the N-type auxiliary layer 12 having composition of, for example, (AlₓGa₁₋ₓ)_{y}In_{1-y}P (0.3≦x≦1) is formed. As an N-type dopant gas, for example, SiH₄ (monosilane), Si₂H₆ (disilane), DESe (diethylselenium), DETe (diethyltellurium) or the like may be used.

Sequentially, by using the same material gases, the active layer 13 is formed that has composition of, for example, (AlₓGa₁₋ₓ)_{y}In_{1-y}P (0.2≦x≦1) where the relative proportion of aluminum is lower than that in the N-type auxiliary layer 12. No dopant gas is used for forming the active layer 13.

Then, sequentially, by using the same material gases, the P-type auxiliary layer 14 is formed that has composition of (AlₓGa₁₋ₓ)_{y}In_{1-y}P (0.3≦×≦1) where the relative proportion of aluminum is higher than that in the active layer 13. For doping a P-type impurity, a dopant gas such as DEZn (diethylzinc), CP2Mg (biscyclopentadienylmagnesium), or the like may be used, or a solid beryllium (Be) source may be used.

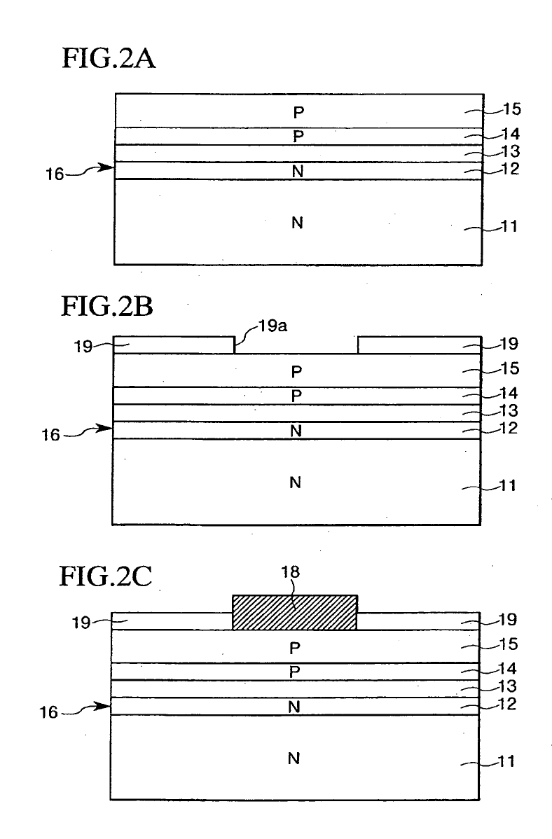

After this, sequentially, the supply of TMA and TMIn is stopped and TEG and PH₃ are introduced to form the window layer 15 made of GaP doped with a P-type impurity. TBP (tertially-butylphosphin) may be used instead of PH₃. In this manner, the semiconductor base 16 shown in FIG. 2A is obtained.

Next, the light transmissive layer 19 made of titanium oxide or the like is formed with the predetermined thickness as described above, on the window layer 15, by vapor deposition, sputtering, plasma CVD, sol-gel process, or the like. In a case where titanium oxide (refraction index n₂=2.2) is used, the thickness T of the light transmissive layer 19 is about 70.45 nm according to the mathematical expression 3, provided that the wavelength λ of the emitted light is 620 nm. After this, the light transmissive layer 19 is patterned by photolithography or the like to form an opening 19a as shown in FIG. 2B.

Then, a metal multilayer film or the like made of Au—Zn, Au—Be—Cr, Au, and the like is deposited on the light transmissive layer 19 and on the window layer 15 exposed in the opening 19a, by vacuum deposition or sputtering, to form a metal film. Then, the metal film on the light transmissive layer 19 is removed by etching or the like to form the anode electrode 18 in the opening 19a as shown in FIG. 2C.

Then, an Au—Ge film, a metal multilayer film made of Au—Ge, Ni, and Au, or the like is deposited on the exposed surface of the N-type substrate 11 by vacuum deposition or sputtering to form the cathode electrode 17.

Then, the obtained stacked object, specifically, the surface of the light transmissive layer 19 and the side surfaces of the stacked object are covered with the protection layer 20 made of epoxy resin or the like. In this manner, the semiconductor light emitting element 10 shown in FIG. 1 is obtained.

As explained above, according to the present embodiment, the light transmissive layer 19 having a predetermined thickness and a refraction index which takes a value between the refraction indexes of the window layer 15 and protection layer 20 is formed between the window layer 15 and the protection layer 20. The light transmissive layer 19 having these characteristics restricts light reflection on the interface between the window layer 15 and the protection layer 20 and realizes a high light extraction efficiency.

The light transmissive layer 19 can be easily formed by using ordinary techniques as mentioned above. Accordingly, there is no need of employing methods for surface roughening, light-diffusing layer forming, etc. for restricting total reflection. Therefore, the semiconductor light emitting element 10 having a high light extraction efficiency with internal light reflection restricted, is realized with a highly-controllable suitable workability, repeatability, and uniformity.

Further, the light transmissive layer 19 is made of an inorganic dielectric material. Therefore, the light transmissive layer 19 is prevented from incurring degradation due to emitted light, a void due to degradation caused by thermal stress, a cut, exfoliation, etc., thereby maintaining a high reliability over time.

The results of measuring output of light by the semiconductor light emitting element 10 fabricated according to the present embodiment will now be explained. FIG. 4 shows results of a test conducted on the semiconductor light emitting element 10 according to the present embodiment having the light transmissive layer 19 (titanium oxide layer), for observing the relationship between the thickness of the light transmissive layer 19 and light output.

In FIG. 4, the light output is indicated as a ratio compared with the light output of an element having no light transmissive layer 19.

The semiconductor light emitting element 10 which was used for the test comprises the N-type substrate 11 made of GaAs, the N-type auxiliary layer 12 made of AlGaInP, the active layer 13 made of AlGaInP, the P-type auxiliary layer 14 made of AlGaInP, the window layer 15 made of GaP, the light transmissive layer 19 made of titanium oxide, and the protection layer 20 made of epoxy resin, and outputs light having a wavelength of 620 nm.

As known from FIG. 4, the semiconductor light emitting element 10 having the light transmissive layer 19 (titanium oxide layer) achieves, regardless of the layer thickness, light output which is improved by about 1.2 to about 1.4 as much as that of the element having no light transmissive layer 19. Accordingly, it is understood that the light output is improved and a higher luminance is realized by providing the light transmissive layer 19.

The output of light detected varies in accordance with the thickness of the light transmissive layer 19. Specifically, the output is large when the thickness of the titanium oxide film is ¼n₂ of the wavelength λ of the emitted light (n₂=2.2), i.e., about 70 nm, while the output is small when the thickness is λ/2n₂, i.e., about 140 nm. From this fact, it is understood that the intensity of emitted light is changed due to light interference in the light transmissive layer 19, and a light most intensified by interference is output when the thickness of the light transmissive layer 19 is (λ/4n₂)×(2m+1) (m=0, 1, 2, . . . ). This means that forming the light transmissive layer 19 with this thickness restricts light reflection and obtains a light emitting element having a further higher luminance.

Next, the output of a lamp fabricated by incorporating a lens into chips of the semiconductor light emitting element 10 was measured. Among the chips of the semiconductor light emitting element 10 used for the above-described test, one having a titanium oxide layer as the light transmissive layer 19 with the thickness of λ/4n (=about 70 nm), and one having no such layer were used.

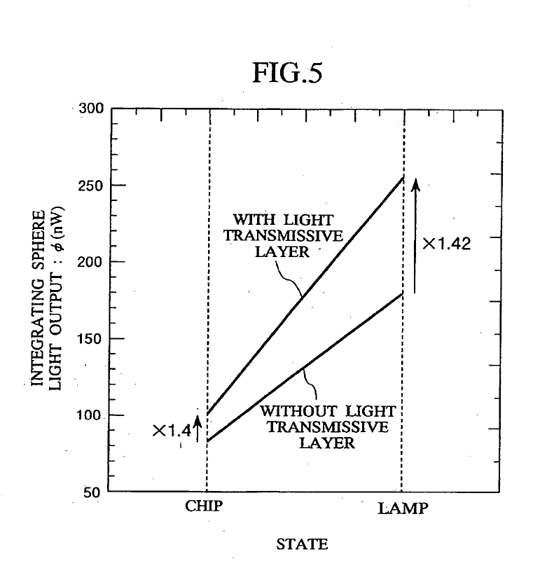

FIG. 5 shows the results of the test for the light output of the chips and lamps in the case where the light transmissive layer 19 was formed or not formed. As shown in FIG. 5, the lamp having the light transmissive layer 19 achieves a light output which is improved by 1.42 as much as that of the lamp having no light transmissive layer 19. From this fact, it is understood that the effect of improving the brightness obtained by the element in the chip state is suitably maintained, or even raised in the state where the element is incorporated into the lamp.

The present invention is not limited to the above-described embodiment, but may be applied or modified in various ways.

In the light emitting element according to the above-described embodiment, for example, a reflection film may be provided between the N-type substrate 11 and the N-type auxiliary layer 12. With the provision of a reflection film made of a highly-conductive and reflexive material such as aluminum or the like, light that is emitted from the active layer 13 toward the N-type substrate 11 can be reflected toward the window layer 15, making it possible to raise the efficiency of utilization of the emitted light.

According to the above-described embodiment, the window layer 15 is formed of a single-layered semiconductor layer made of GaP or the like. However, the constitution of the window layer 15 is not limited to this, but the window layer 15 may be a multilayered structure. For example, the window layer 15 may have a structure in which an AlGaAs semiconductor layer and an AlGaInP semiconductor layer are stacked, and the anode electrode 18 may be formed on the AlGaInP semiconductor layer.

In the above-described embodiment, an ordinary resin sealant material which is highly transparent may be used for the protection layer 20. In this case, the refraction index or the like of the light transmissive layer 19 may be set based on the refraction index of the material used for the protection layer 20. Further, the protection layer 20 may be omitted. In this case, a material having a suitable refraction index based on the refraction index of the atmosphere may be used for the light transmissive layer 19.

According to the above-described embodiment, the light transmissive layer 19 is made of an inorganic dielectric material. However, an organic resin material, for example, silicone resin or the like may be used as long as such a material shows a refraction index satisfying the above-described mathematical expression 2.

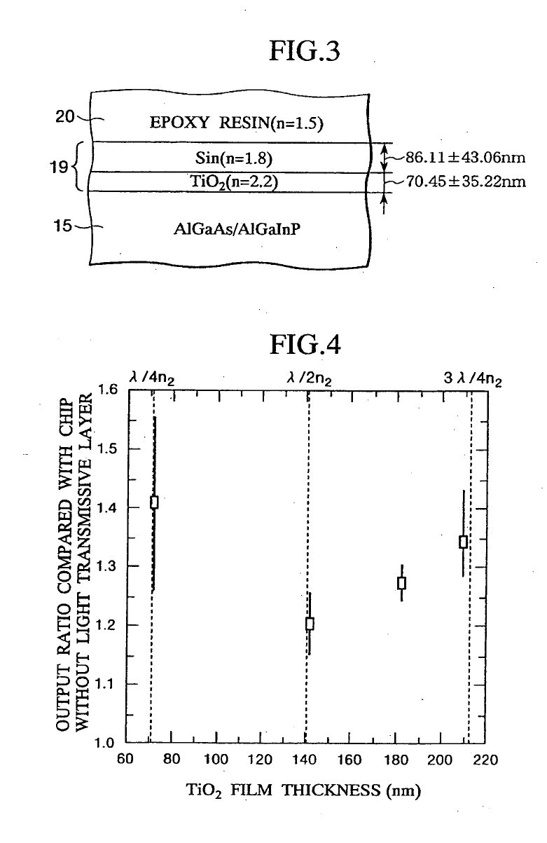

According to the above-described embodiment, the light transmissive layer 19 is formed of a single layer. However, as shown in FIG. 3, the light transmissive layer 19 may be formed of a multilayered stacked film. In this case, each layer is formed with a refraction index and thickness different from those of the layers such that these values satisfy the mathematical expression 2 and the mathematical expression 3. In FIG. 3, the light transmissive layer 19 is formed of two layers, but the number of layers included is not limited to two.

A case will be explained below where a two-layered light transmissive layer 19 formed of a titanium oxide layer and a silicon nitride layer is formed on the window layer 15 having a stacked structure of AlGaAs and AlGaInP.

The refraction index of the AlGaINP semiconductor is 3.3, the refraction index of titanium oxide is 2.2, the refraction index of silicon nitride is 1.8, and the refraction index of epoxy resin to be formed on the silicon nitride layer is 1.5. Accordingly, the refraction index of each layer satisfies the mathematical expression 2. According to the mathematical expression 2, the range of the refraction index of the layer to form the light transmissive layer 19 is defined based on the refraction indexes of the layers adjoining the layer from both sides.

To be more specific, the refraction index 2.2 of titanium oxide falls within the range of not smaller than 1.8 (=(3.3×1.8)^{1/2}×0.8) and not larger than 2.7 (=(3.3×1.8)^{1/2}×1.2), satisfying the mathematical expression 2. The refraction index 1.8 of silicon nitride falls within the range of not smaller than 1.53 (=(2.2×1.5)^{1/2}×0.8) and not larger than 2.3 (=(2.2×1.5)^{1/2}×1.2), satisfying the mathematical expression 2. Therefore, as described above, reflection on the interface is restricted.

Further, by setting the thickness of each layer of the two-layered light transmissive layer 19 so as to satisfy the mathematical expression 3, light intensified by interference in the light transmissive layer 19 is emitted to the outside world. Specifically, in a manner to satisfy the mathematical expression 3, the thickness of the titanium oxide layer is set within the range of 70.45 nm (=620 nm/(4×2.2), m=0)±35.22 nm (=620 nm/(8×2.2)), and the thickness of the silicon nitride layer is set within the range of 86.11 nm (=620 nm/(4×1.8))±43.06 nm (=620 nm/(8×1.8)).

The titanium oxide layer and the silicon nitride layer can both be easily formed with a good controllability and repeatability by using an ordinary technique such as vapor deposition, sputtering, plasma CVD, sol-gel process, etc.

As described above, as long as the mathematical expression 2 and the mathematical expression 3 are satisfied, the light transmissive layer 19 may be formed of many layers, which may further increase the reflection restriction effect. However, if the light transmissive layer 19 includes six or more layers, the total thickness of the light transmissive layer 19 becomes so large that the attenuation of light while passing through the light transmissive layer 19 becomes remarkable. Accordingly, it is preferred that the light transmissive layer 19 include five or less layers.

In the above-described embodiment, the case has been explained where the semiconductor light emitting element 10 of the present invention is applied to a light emitting diode. However, the light emitting element 10 can unlimitedly be applied to any electroluminescence-type semiconductor element such as a semiconductor laser, etc.

Various embodiments and changes may be made thereunto without departing from the broad spirit and scope of the invention. The above-described embodiment is intended to illustrate the present invention, not to limit the scope of the present invention. The scope of the present invention is shown by the attached claims rather than the embodiment. Various modifications made within the meaning of an equivalent of the claims of the invention and within the claims are to be regarded to be in the scope of the present invention.

1. A semiconductor light emitting element comprising:
a semiconductor layer which forms an optical window;
a first light transmissive layer which is formed on said semiconductor layer; and
a second light transmissive layer which is formed on said first light transmissive layer,
wherein
a refraction index n₂ of said first light transmissive layer is within a range of not smaller than {(n₁×n₃)^{1/2}×0.8} and not larger than {(n₁×n₃)^{1/2}×1.2} where n₁ represents a refraction index of said semiconductor layer and n₃ represents a refraction index of said second light transmissive layer, and
a thickness of said first light transmissive layer is within a range of not smaller than {(λ/4n₂)×(2m+1)−(λ/8n₂)} and not larger than {(λ/4n₂)×(2m+1)+(λ/8n₂)} where λ represents a wavelength of emitted light and m represents a positive integer not smaller than 0.

2. The semiconductor light emitting element according to claim 1, wherein
said first light transmissive layer is formed by stacking a plurality of layers having different refraction indexes; and
a refraction index n₂ⱼ of each of said layers of said first light transmissive layer is within a range defined between a refraction index n₂ᵢ of a layer adjoining said each layer at a side of said semiconductor layer and a refraction index n₂ₖ of a layer adjoining said each layer at a side of said second light transmissive layer.

3. The semiconductor light emitting element according to claim 2, wherein
the refraction index n₂ⱼ of each layer of said first light transmissive layer is within a range of not smaller than {(n₂ᵢ×n₂ₖ)^{1/2}×0.8} and not larger than {(n₂ᵢ×n₂ₖ)^{1/2}×1.2}.

4. The semiconductor light emitting element according to claim 2, wherein
a thickness of each layer of said first light transmissive layer is within a range of not smaller than {(λ/4n₂ⱼ)×(2l+1)−(λ/8n₂ⱼ)} and not larger than {(λ/4n₂ⱼ)'(2l+1)+(λ/8n₂ⱼ)} where λ represents a wavelength of emitted light and 1 represents a positive integer not smaller than 0.

5. The semiconductor light emitting element according to claim 1, wherein
said second light transmissive layer is formed of a protection film.

6. The semiconductor light emitting element according to claim 1, wherein
said first light transmissive layer is made of an inorganic dielectric material.

7. A semiconductor light emitting element comprising:
a semiconductor layer which forms an optical window; and
a first light transmissive layer which is formed on said semiconductor layer,
wherein
said light emitting element is structured such that light emitted from said semiconductor layer is emitted to external atmosphere by passing through said first light transmissive layer,
a refraction index n₂ of said first light transmissive layer is within a range of not smaller than {(n₁×n₃)^{1/2}×0.8} and not larger than {(n₁×n₃)^{1/2}×1.2} where n₁ represents a refraction index of said semiconductor layer and n₃ represents a refraction index of atmosphere, and
a thickness of said first light transmissive layer is within a range of not smaller than {(λ/4n₂)×(2m+1)−(λ/8n₂)} and not larger than {(λ/4n₂)×(2m+1)+(λ/8n₂)} where λ represents a wavelength of emitted light and m represents a positive integer not smaller than 0.

8. A semiconductor light emitting element comprising:
a semiconductor layer which emits light having a wavelength λ caused by recombination of holes and electrons; and
a first light transmissive layer which is stacked on said semiconductor layer,
wherein
a second light transmissive layer is stacked on sad first light transmissive layer at a side opposite to a side said semiconductor layer is disposed,
said light emitting element is structured such that light emitted from said semiconductor layer is guided to said second light transmissive layer via said first light transmissive layer and thus guided to outside,
at least a part of said semiconductor layer from which part light is emitted to said first light transmissive layer has a refraction index n₁, said first light transmissive layer has a refraction index n₂, and said second light transmissive layer has a refraction index n₃,
a refraction index n₂ of said first light transmissive layer is within a range of not smaller than {(n₁×n₃)^{1/2}×0.8} and not larger than {(n₁×n₃)^{1/2}×1.2}, and
a thickness of said first light transmissive layer is within a range of not smaller than {(λ/4n₂)×(2m+1)−(λ/8n₂)} and not larger than {(λ/4n₂)×(2m+1)+(λ/8n₂)} where m represents a positive integer not smaller than 0.

9. The semiconductor light emitting element according to claim 8, wherein
said semiconductor layer includes an N-type carrier injection layer for generating electrons, a P-type carrier injection layer for generating holes, and an active layer for generating light by recombination of electrons injected from said N-type carrier injection layer and holes injected from said P-type carrier injection layer,
said N-type carrier injection layer, said active layer, said P-type carrier injection layer, and said first light transmissive layer are stacked in this order, and
a reflection film is formed on any part that is included in a region starting from said active layer toward said N-type carrier injection layer, so that light emitted from said active layer toward said N-type carrier injection layer is reflected on said reflection film and thus guided toward said first light transmissive layer.

10. The semiconductor light emitting element according to claim 8, wherein
a protection film having the refraction index n₃ is formed as said second light transmissive layer.

11. The semiconductor light emitting element according to claim 8, wherein
said second light transmissive layer is external atmosphere, and
light emitted from said semiconductor layer is emitted to the external atmosphere by passing through said first light transmissive layer.

12. A fabrication method of a semiconductor light emitting element including a semiconductor layer forming an optical window, a first light transmissive layer formed on said semiconductor layer, and a second light transmissive layer formed on said first light transmissive layer, said method comprising
forming said first light transmissive layer by using a material having a refraction index n₂ which is within a range of not smaller than {(n₁×n₃)^{1/2}×0.8} and not larger than {(n₁×n₃)^{1/2}×1.2} (where n₁ represents a refraction index of said semiconductor layer and n₃ represents a refraction index of said second light transmissive layer), and by giving a thickness which is within a range of not smaller than {(λ/4n₂)×(2m+1)−(λ/8n₂)} and not larger than {(λ/4n₂)×(2m+1)+(λ/8n₂)} (where λ represents a wavelength of emitted light and m represents a positive integer not smaller than 0).

13. The fabrication method of the semiconductor light emitting element according to claim 12, wherein
said first light transmissive layer is formed by stacking a plurality of layers having different refraction indexes, and
each of said layers of said first light transmissive layer is formed by using a material having a refraction index n₂ⱼ which is within a range of not smaller than {(n₂ᵢ×n₂ₖ)^{1/2}×0.8} and not larger than {(n₂ᵢ×n₂ₖ)^{1/2}×1.2} (where n₂ᵢ represents a refraction index of a layer adjoining said each layer at a side of said semiconductor layer and n₂ₖ represents a refraction index of a layer adjoining said each layer at a side of said second light transmissive layer), and by giving a thickness which is within a range of not smaller than {(λ/4n₂ⱼ)×(2l+1)−(λ/8n₂ⱼ)} and not larger than {(λ/4n₂ⱼ)×(2l+1)+(λ/8n₂ⱼ)} (where λ represents a wavelength of emitted light and 1 represents a positive integer not smaller than 0).
